(19) United States
(12) Patent Application Publication
(10) Pub. No.: US 2026/0112588 A1
(43) Pub. Date: Apr. 23, 2026

(54) PLASMA PROCESSING METHOD AND PLASMA PROCESSING APPARATUS

(71) Applicant: Tokyo Electron Limited, Tokyo (JP)

(72) Inventors: Hirotaka MIKAMI, Miyagi (JP); Takehito WATANABE, Miyagi (JP); Rei TAKAHASHI, Miyagi (JP)

(21) Appl. No.: 19/429,069

(22) Filed: Dec. 22, 2025

Related U.S. Application Data
(63) Continuation of application No. PCT/JP2024/023536, filed on Jun. 28, 2024.

(30) Foreign Application Priority Data
Jul. 11, 2023 (JP) 2023-113579

(51) Int. Cl. H01J 37/32

(52) U.S. Cl. CPC H01J 37/32862; H01J 37/32449; H01J 37/32669; H01J 37/32467

(57) ABSTRACT

A plasma processing method executed by a plasma processing apparatus is provided. The plasma processing apparatus includes: a chamber; a substrate support disposed inside the chamber; an upper electrode facing a substrate support surface of the substrate support; an electromagnet disposed above the chamber; a plasma source configured to generate plasma inside the chamber; a DC power supply electrically coupled to the upper electrode; and one or more processors and one or more memories storing instructions that, when executed by the one or more processors, cause the plasma processing apparatus to perform the plasma processing method. The plasma processing method includes: generating plasma from a processing gas inside the chamber by the plasma source; and controlling the plasma by applying a DC voltage to the upper electrode by the DC power supply while generating a magnetic field inside the chamber by the electromagnet, thereby cleaning parts inside the chamber.

### CROSS-REFERENCE TO RELATED APPLICATION

This application is a continuation of International Application No. PCT/JP2024/023536, filed on June 28, 2024 and designating the U.S., which claims priority to Japanese Patent Application No. 2023-113579, filed on July 11, 2023. The contents of these applications are incorporated herein by reference in their entirety.

### TECHNICAL FIELD

The present disclosure relates to a plasma processing method and a plasma processing apparatus.

### BACKGROUND

Japanese Unexamined Patent Publication No. 2015-170611, for example, discloses a cleaning method for a plasma processing apparatus that removes deposits accumulated on the upper electrode. In this method, the deposits are removed by supplying current to multiple annular coils disposed above the chamber, thereby generating a magnetic field.

### SUMMARY

According to one aspect of the present disclosure, a plasma processing method performed by a plasma processing apparatus is provided. The plasma processing apparatus includes: a chamber; a substrate support disposed inside the chamber; an upper electrode facing a substrate support surface of the substrate support; an electromagnet disposed above the chamber; a plasma source configured to generate plasma inside the chamber; a DC power supply electrically coupled to the upper electrode; and one or more processors and one or more memories storing instructions that, when executed by the one or more processors, cause the plasma processing apparatus to perform the plasma processing method, the plasma processing method comprising:

generating plasma from a processing gas inside the chamber by the plasma source; and

controlling the plasma by applying a DC voltage to the upper electrode by the DC power supply while generating a magnetic field inside the chamber by the electromagnet, thereby cleaning parts inside the chamber.

### BRIEF DESCRIPTION OF THE DRAWINGS

FIG. 1 is a diagram illustrating an example of a schematic configuration of a plasma processing apparatus according to an embodiment;

FIG. 2 is a diagram illustrating an arrangement example of a plurality of coils in an electromagnet according to the embodiment;

FIG. 3A is a diagram illustrating an example of a magnetic field generated by an electromagnet;

FIG. 3B is a diagram illustrating an example of a magnetic field generated by an electromagnet;

FIG. 4 illustrates an experimental example 1 of cleaning parts inside the chamber according to an embodiment;

FIG. 5A illustrates cleaning parts inside the chamber according to an embodiment;

FIG. 5B illustrates cleaning parts inside the chamber according to an embodiment;

FIG. 5C illustrates cleaning parts inside the chamber according to an embodiment;

FIG. 6 illustrates an experimental example 2 of cleaning parts inside the chamber according to an embodiment;

FIG. 7 is a flowchart illustrating an example of a plasma processing method according to an embodiment;

FIG. 8A illustrates an example of cleaning results of parts inside the chamber; and

FIG. 8B illustrates an example of cleaning results of parts inside the chamber.

### DETAILED DESCRIPTION

Hereinafter, an embodiment of the present disclosure will be described with reference to the drawings. In each of the drawings, the same components are denoted by the same reference numerals, and redundant descriptions may be omitted.

### Plasma Processing Apparatus

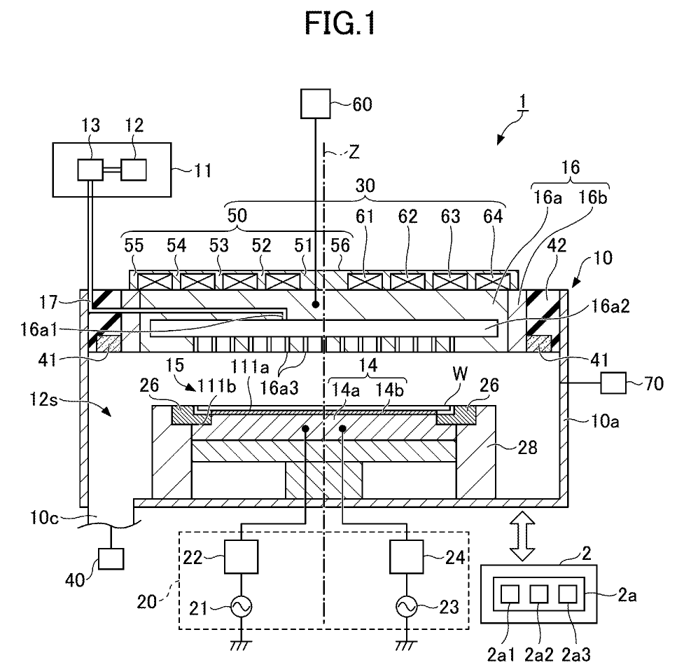

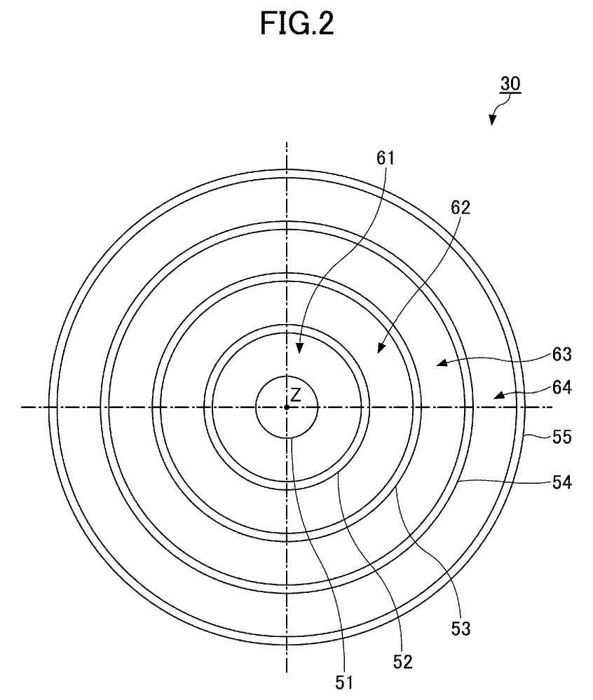

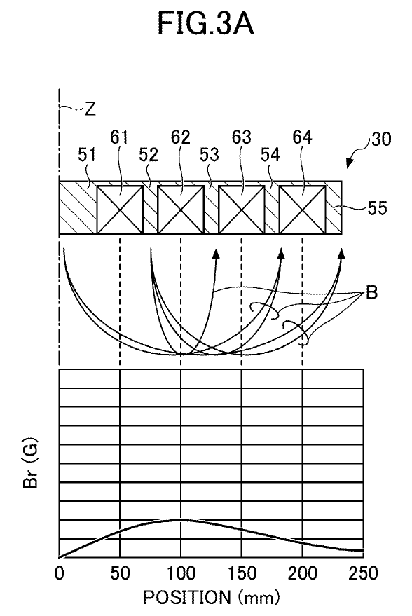

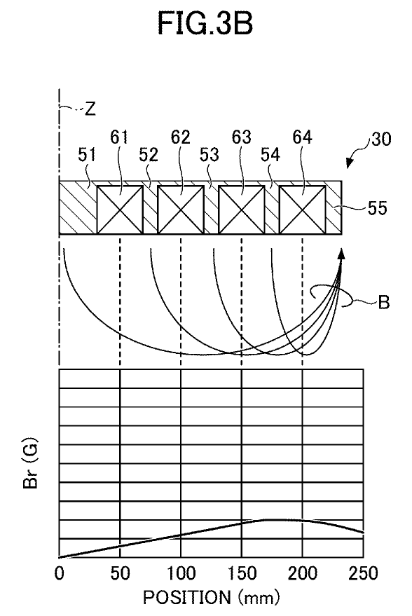

A plasma processing apparatus according to an embodiment will be described with reference to FIGS. 1 to 3B. FIG. 1 is a diagram illustrating an example of a schematic configuration of a plasma processing apparatus according to an embodiment. FIG. 2 is a diagram illustrating an arrangement example of a plurality of coils included in an electromagnet disposed in the plasma processing apparatus according to the embodiment. FIG. 3A and 3B are each a diagram illustrating an example of a magnetic field generated by the electromagnet.

A plasma processing apparatus 1 includes a chamber 10, a gas supply 11, a power supply 20, an electromagnet 30, and an exhaust device 40. The plasma processing apparatus 1 further includes a substrate support 15 and a gas introducer. The gas introducer is configured to introduce at least one processing gas into the chamber 10. The gas introducer includes a showerhead 16. The substrate support 15 is disposed inside the chamber 10. The showerhead 16 is disposed above the substrate support 15 so as to face the substrate support 15. In one embodiment, the showerhead 16 constitutes at least a portion of a ceiling of the chamber 10.

The chamber 10 includes a plasma processing space 12s defined by the showerhead 16, side walls 10a of the chamber 10, and the substrate support 15. The showerhead 16 is disk-shaped, and its center axis is disposed to substantially coincide with a center axis Z passing through the center of a substrate W in the vertical direction.

The chamber 10 includes at least one gas supply port for supplying at least one processing gas to the plasma processing space 12s and at least one gas exhaust port for exhausting gas from the plasma processing space 12s. The chamber 10 is grounded. The showerhead 16 and the substrate support 15 are electrically isolated from a housing of the chamber 10.

The substrate support 15 includes a body 14 and an edge ring 26. The body 14 includes a base 14a and an electrostatic chuck 14b. The base 14a includes an electrically conductive member. The electrically conductive member of the base 14a may function as a lower electrode. The electrostatic chuck 14b is disposed on the base 14a and includes a ceramic member and an electrostatic electrode (not illustrated) disposed within the ceramic member. The edge ring 26 and a support 28 are annular members. The support 28 supports the outer periphery of the edge ring 26, and includes the periphery of the edge ring 26 and the body 14. The edge ring 26 is made of a conductive material or an insulating material, such as silicon or SiC. The support 28 is made of an insulating material, such as quartz.

The body 14 includes a central region 111a for supporting the substrate W and an annular region 111b for supporting the edge ring 26. The wafer is an example of the substrate W. The annular region 111b of the body 14 surrounds the central region 111a of the body 14 in plan view. The substrate W is disposed on the central region 111a of the body 14, and the edge ring 26 is disposed on the annular region 111b of the body 14 and the support 28 so as to surround the substrate W on the central region 111a of the body 14. Therefore, the central region 111a is also called a substrate support surface for supporting the substrate W, and the annular region 111b is also called a ring support surface for supporting the edge ring 26. When the substrate W is placed on the electrostatic chuck 14b, the center axis Z passing through the central portion of the substrate W in the vertical direction substantially coincides with the center axes of the base 14a and the electrostatic chuck 14b.

The substrate support 15 may also include a temperature control module configured to adjust a temperature of at least one of the electrostatic chuck 14b, the edge ring 26, and the substrate W to a target temperature. The temperature control module may include a heater, a heat transfer medium, a flow channel or a combination thereof. A heat transfer fluid such as brine or gas flows through the flow channel. In one embodiment, a flow channel is formed within the base 14a and one or more heaters are disposed within the electrostatic chuck 14b. The substrate support 15 may also include a heat transfer gas supply configured to supply heat transfer gas to a gap between the backside of the substrate W and the central region 111a.

The showerhead 16 is configured to introduce at least one processing gas into the plasma processing space 12s from the gas supply 11. The showerhead 16 has at least one gas supply port 16a1, at least one gas diffusion chamber 16a2, and a plurality of gas introduction holes 16a3. The processing gas is supplied to the gas supply port 16a1 via a gas passage 17 connected to the gas supply 11, passes through the gas diffusion chamber 16a2, and is introduced into the plasma processing space 12s from the plurality of gas introduction holes 16a3. The showerhead 16 includes at least one upper electrode. The showerhead 16 according to the present embodiment includes an inner upper electrode 16a and an outer upper electrode 16b surrounding the upper electrode 16a. The upper electrode 16a is disk-shaped, and the outer upper electrode 16b is ring-shaped. The inner upper electrode 16a faces the substrate support surface of the substrate support 15. The outer upper electrode 16b is disposed radially on the outer peripheral side of the substrate support 15. A ground ring 41 surrounding the outer periphery of the upper electrode 16b is disposed on a surface of the top portion of the chamber 10 in contact with the plasma processing space 12s. The ground ring 41 is made of, for example, silicon (Si) and is grounded. An insulating member 42 is disposed so as to surround the outer periphery of the ground ring 41 and the upper electrode 16b. The ground ring 41 and the insulating member 42 are ring-shaped.

A gas supply 11 may include at least one gas source 12 and at least one flow controller 13. In one embodiment, the gas supply 11 is configured to supply at least one processing gas from a corresponding gas source 12 to the showerhead 16 via a corresponding flow controller 13. Each flow controller 13 may include, for example, a mass flow controller or a pressure-controlled flow controller. In addition, the gas supply 11 may include one or more flow modulation devices that modulate or pulse a flow rate of at least one processing gas.

The power supply 20 is coupled to the chamber 10 via at least one impedance matching circuit. The power supply 20 includes an RF power supply 21 and an RF power supply 23. The RF power supply 21 is coupled to the bottom electrode via an impedance matching circuit 22 and is configured to provide an RF signal (RF power) to the bottom electrode. In one embodiment, the RF power supply 21 provides a source RF signal (source RF power) for plasma generation to the bottom electrode. The RF power supply 21 may provide a source RF signal (source RF power) to the upper electrode.

This causes a plasma to be formed from at least one processing gas supplied to the plasma processing space 12s. Accordingly, the RF power supply 21 may function as at least part of a plasma source configured to generate a plasma from one or more processing gases in the chamber 10.

The RF power supply 23 is coupled to the bottom electrode via the impedance matching circuit 24 and is configured to provide an RF signal (RF power) to the bottom electrode. In one embodiment, the RF power supply 23 provides a bias RF signal (bias RF power) to the bottom electrode. By providing the bias RF signal from the RF power supply 23 to the bottom electrode, a bias potential is generated in the substrate W to draw the ions of the formed plasma into the substrate W.

The source RF signal has a frequency in the range of 10 MHz to 150 MHz. The frequency of the bias RF signal may be the same as or different from the frequency of the source RF signal. In one embodiment, the bias RF signal has a frequency that is lower than the frequency of the source RF signal. In one embodiment, the bias RF signal has a frequency in the range of 100 kHz to 60 MHz. In one embodiment, at least one of the source RF signal and the bias RF signal may be pulsed.

In one embodiment, the power supply 20 has a DC power supply 60 electrically coupled to the upper electrode 16a (showerhead 16). The DC power supply 60 is configured to apply a DC signal (DC voltage) to the upper electrode 16a. In one embodiment, the DC power supply 60 applies a DC signal (DC voltage) of negative polarity to the upper electrode 16a. The DC signal may be pulsed.

The exhaust device 40 may be connected, for example, to a gas exhaust port 10c disposed at the bottom of the chamber 10. The exhaust device 40 may include a pressure regulating valve and a vacuum pump. The pressure regulating valve regulates the pressure inside the plasma processing space 12s. The vacuum pump may include a turbomolecular pump, a dry pump, or a combination thereof. The pressure inside the chamber 10 (plasma processing space 12s) is detected by a pressure detector 70 attached to the chamber 10. The pressure inside the chamber 10 detected by the pressure detector 70 is transmitted to a controller 2 and used by the controller 2 to control the pressure inside the chamber 10.

The controller 2 processes computer-executable instructions for causing the plasma processing apparatus 1 to perform the various steps described herein. The controller 2 may be configured to control respective components of the plasma processing apparatus 1 to execute the various steps described herein. In one embodiment, a part or the entirety of the controller 2 may be included in the plasma processing apparatus 1. The controller 2 may include a processor 2a1, a storage 2a2, and a communication interface 2a3. The controller 2 may be implemented by, for example, a computer 2a. The processor 2a1 may be configured to perform various control operations by reading a program from the storage 2a2 and executing the read program. The program may be stored in advance in the storage 2a2, or may be acquired through a medium as needed. The acquired program is stored in the storage 2a2, read therefrom by the processor 2a1, and executed. The medium may be any storage medium readable by the computer 2a, or a communication line connected to the communication interface 2a3. The processor 2a1 may be a CPU (Central Processing Unit). The storage 2a2 may include a RAM (Random Access Memory), ROM (Read Only Memory), HDD (Hard Disk Drive), SSD (Solid State Drive), or a combination thereof. The communication interface 2a3 may communicate with the plasma processing apparatus 1 via a communication line such as a LAN (Local Area Network).

The electromagnet 30 is disposed above the chamber (just above the showerhead 16). The electromagnet 30 has a core member 50 and a coils 61 to 64. The core member 50 has a structure in which a columnar portion 51, a plurality of cylindrical portions 52 to 55, and a base portion 56 are integrally formed, and is composed of a magnetic material. The base portion 56 has a substantially circular disk shape, and its center axis is provided along the center axis Z. The columnar portion 51 and the plurality of cylindrical portions 52 to 55 are arranged to project downward from the lower surface of the base portion 56. The columnar portion 51 has a substantially cylindrical shape, and its center axis is provided along the center axis Z.

Each of the cylindrical portions 52 to 55 has a cylindrical shape extending in the center axis Z direction. As illustrated in FIG. 2, the cylindrical portions 52 to 55 constitute a plurality of concentric circles around the center axis Z. Specifically, the radius of the cylindrical portion 52 is larger than the radius of the columnar portion 51. The radius of the cylindrical portion 53 is larger than the radius of the cylindrical portion 52. The radius of the cylindrical portion 54 is larger than the radius of the cylindrical portion 53. The radius of the cylindrical portion 55 is larger than the radius of the cylindrical portion 54.

A groove is defined between the columnar portion 51 and the cylindrical portion 52. As illustrated in FIG. 1, the groove accommodates a coil 61 wound along an outer peripheral surface of the columnar portion 51. A groove is also defined between the cylindrical portion 52 and a cylindrical portion 53, and the groove accommodates a coil 62 wound along an outer peripheral surface of the cylindrical portion 52. Similarly, a groove is defined between the cylindrical portion 53 and a cylindrical portion 54, and the groove accommodates a coil 63 wound along an outer peripheral surface of the cylindrical portion 53. Furthermore, a groove is defined between the cylindrical portion 54 and a cylindrical portion 55, and the groove accommodates a coil 64 wound along an outer peripheral surface of the cylindrical portion 54. Both ends of the coils 61 to 64 are connected to a power supply (not illustrated). The supply and interruption of current to each of the coils 61 to 64, as well as the current value, are controlled based on a control signal from the controller 2.

According to the electromagnet 30 having the above configuration, a magnetic field B having a horizontal magnetic field component Br along the radial direction with respect to the central axis Z can be formed in the plasma processing space 12s by supplying a current from a power source to one or more coils among the coils 61 to 64. FIGS. 3A and 3B illustrate examples of magnetic fields formed by the electromagnet 30.

The upper diagram of FIG. 3A illustrates a cross section of the electromagnet 30 in a half plane with respect to the central axis Z and a magnetic field B when a current is supplied to the coil 62, and the lower view of FIG. 3A illustrates an intensity distribution of the horizontal magnetic field component Br when a current is supplied to the coil 62.

The upper diagram of FIG. 3B illustrates a cross section of the electromagnet 30 in a half plane with respect to the central axis Z and a magnetic field B when a current is supplied to the coil 64, and the lower view of FIG. 3B illustrates an intensity distribution of the horizontal magnetic field component Br when a current is supplied to the coil 64. In the graphs illustrated in the lower view of FIG. 3A and the lower view of FIG. 3B, the abscissa indicates a position in the radial direction when the position of the central axis Z is 0 mm, and the ordinate indicates an intensity (magnetic flux density) of the horizontal magnetic field component Br.

When a current is supplied to the coil 62 of the electromagnet 30, a magnetic field B as illustrated in the upper diagram of FIG. 3A is formed. That is, a magnetic field B directed from the ends of the columnar portion 51 and the cylindrical portion 52 on the plasma processing space 12s side to the ends of the cylindrical portion 53 to 55 on the plasma processing space 12s side is formed. The intensity distribution of the horizontal magnetic field component Br of such a magnetic field B in the radial direction has a peak below the central portion of the coil 62 as illustrated in the lower graph of FIG. 3A. In one example, the center position of the coil 62 is located about 100 mm from the central axis Z, and when a substrate W having a diameter of 300 mm is processed, the center position of the coil 62 is located radially outside the edge of the substrate W, that is, located at an intermediate position between the center and the edge of the substrate W.

When a current is supplied to the coil 64 of the electromagnet 30, a magnetic field B as illustrated in the upper diagram of FIG. 3B is formed. That is, a magnetic field B directed from the end portions of the columnar portion 51 and the cylindrical portion 52 to 54 on the plasma processing space 12s side to the end portion of the cylindrical portion 55 on the plasma processing space 12s side is formed. The intensity distribution of the horizontal magnetic field component Br of such a magnetic field B in the radial direction is an intensity distribution having a peak below the center of the coil 64, as illustrated in the lower graph of FIG. 3B. In one example, the center position of the coil 64 is about 200 mm from the central axis Z, and when the substrate W having a diameter of 300 mm (radius of 150 mm) is processed, the center position of the coil 64 is located outside the edge of the substrate W in the radial direction, that is, located at the position of the edge ring 26.

In this manner, a current is supplied to at least one of the coils 61 to 64 of the electromagnet 30. Thus, the radial intensity distribution of the horizontal magnetic field component Br of the magnetic field B forms a magnetic field distribution having a large horizontal component below the coil supplied with the current in the plasma processing space 12s. Therefore, a magnetic field distribution suitable for obtaining a uniform plasma density distribution in the whole plasma can be efficiently formed in the plasma processing space 12s by the electromagnet 30.

In cleaning parts inside the chamber 10, a predetermined cleaning gas is introduced into the chamber 10 via the shower head 16, and RF power is supplied to the lower electrode (base 14a) from the RF power supply 21 and, if necessary, the RF power supply 23. Thus, the cleaning gas is converted into plasma, and deposits accumulated on the surfaces of the parts inside the chamber 10 are removed by the action of the plasma.

At this time, the controller 2 controls the plasma so that the whole plasma has a uniform plasma density distribution by supplying a current to at least one of the coils 61 to 64. Thus, the cleaning rate of the parts inside the chamber 10 can be raised as a whole.

On the other hand, deposits accumulated on the surfaces of the parts inside the chamber are larger as the parts are closer to the substrate W. Therefore, among the parts inside the chamber, the part to which the largest amount of deposition adheres is located near the central portion of the inner upper electrode 16a facing the substrate support surface of the substrate support 15.

Therefore, in addition to controlling the plasma so as to have a uniform plasma density distribution by generating a magnetic field inside the chamber 10 with the electromagnet 30, it is desirable to provide a control parameter (hereinafter referred to as “control knob”) that can locally increase the cleaning rate near the central portion of the upper electrode 16a. Therefore, in the plasma processing method according to the present embodiment, a DC voltage applied from the DC power supply 60 to the upper electrode 16a is used as one of the control knobs for locally controlling the plasma density distribution. That is, the controller 2 simultaneously uses two control knobs, namely, the electromagnet 30 and the DC power supply 60. Thus, by applying a DC voltage to the upper electrode 16a from the DC power supply 60 while generating a magnetic field inside the chamber 10, both overall control and local control of the plasma are performed. As a result, while improving the cleaning efficiency of all the parts inside the chamber, the cleaning of the central portion of the upper electrode 16a is further enhanced, and deposits can be efficiently removed from the parts inside the chamber, including the upper electrode 16a. Consequently, the cleaning time of the parts inside the chamber can be shortened, and the throughput can be improved.

### Experimental Example 1 of Cleaning Parts Inside Chamber

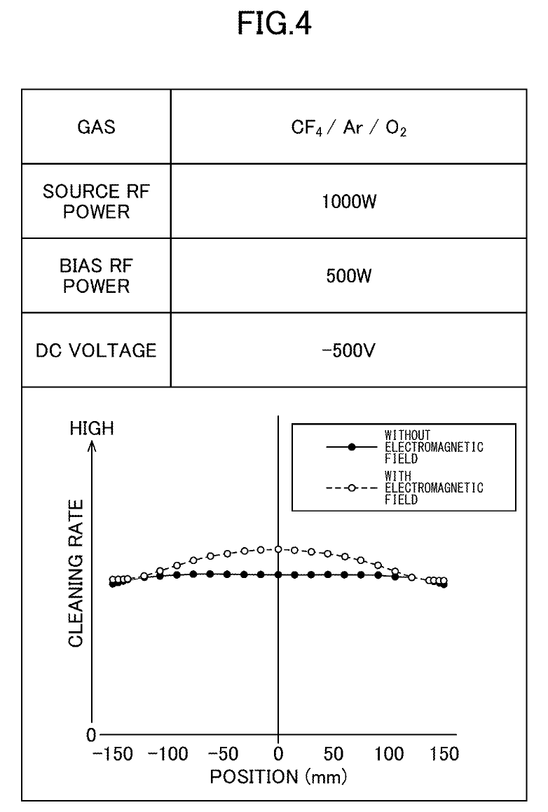

Experimental Example 1 of cleaning parts inside the chamber according to one embodiment will be described with reference to FIG. 4. The cleaning conditions in Experimental Example 1 are as follows. The plasma processing method performed under the cleaning conditions in Experimental Example 1 is an example of the plasma processing method according to one embodiment.

### Cleaning conditions in Experimental Example 1

Gas: CF₄, Ar, O₂

Source RF power: 1000 W

Bias RF power: 500 W

DC voltage: −500 V

Current supplied to coils 61–64: 0/0/0/10 dA (deciamperes)

Chamber pressure: 20 mTorr (2.67 Pa)

Under the cleaning conditions of Experiment 1, a processing gas (cleaning gas) consisting of CF₄ gas, Ar gas, and O₂ gas was supplied from gas supply 11, and introduced into the plasma processing space 12s (from the shower head 16. Source RF power of 1000 W was supplied from the RF power supply 21 to the lower electrode (base 14a). Bias RF power of 500 W was supplied from the RF power supply 23 to the lower electrode (base 14a). Thus, plasma was generated from a processing gas in plasma processing space 12s. DC voltage of -500 V was applied from the DC power supply 60 to the upper electrode 16a.

The graph in FIG. 4 illustrates the results of Experiment Example 1 in which the cleaning rate (etching rate) at each position in the radial direction of the upper electrode 16a was measured. The plots of white circles in FIG. 4 are cleaning rates at respective positions in the radial direction of the upper electrode 16a when the electromagnetic field is generated by the electromagnet 30, and the plots of black circles in FIG. 4 are cleaning rates at respective positions in the radial direction of the upper electrode 16a when the electromagnetic field is not generated by the electromagnet 30. That is, the plot indicated by the black circles indicates a case where no magnetic field is generated in any of the coils 61 to 64 of the electromagnet 30. The plot indicated by the white circles indicates a case where a current value of 0/0/0/10 dA (deciamperes) is supplied to the coils 61 to 64 of the electromagnet 30 and a magnetic field is generated in the plasma processing space 12s.

In Experimental Example 1, when no electromagnetic field was generated by the electromagnet 30, the cleaning rate of the surface of the upper electrode 16a was substantially uniform overall. On the other hand, when an electromagnetic field was generated by the electromagnet 30, the cleaning rate further increased with a peak at the center (0 mm on the horizontal axis) of the upper electrode 16a and gradually decreased toward the outer periphery. The cleaning rate near the outermost periphery of the upper electrode 16a was almost the same as that in the case where no electromagnetic field was generated.

In this Experimental Example 1, in the case of “with electromagnetic field”, the electromagnet 30 and the DC power supply 60 were used as control knobs in a superimposed manner. As a result, compared with the case of “without electromagnetic field”, in which only the DC power supply 60 was used as a control knob, the cleaning rate at the central portion of the upper electrode 16a was increased, and therefore the parts inside the chamber could be cleaned more efficiently. That is, the DC voltage was applied uniformly over the entire upper electrode 16a. Therefore, the in-plane uniformity of cleaning across the entire upper electrode 16a remained unchanged, while the cleaning rate of the entire upper electrode 16a was increased by the electromagnetic field. Moreover, the plasma density at the central portion of the plasma could be locally increased. Consequently, by increasing the cleaning rate at the central portion of the upper electrode 16a where the largest amount of deposits adhered, the cleaning of the upper electrode 16a could be performed efficiently. As a result, the cleaning time could be shortened, and the throughput could be improved. In addition, by performing cleaning with a locally increased cleaning rate at the central portion of the upper electrode 16a, unnecessary wear of other parts could be suppressed.

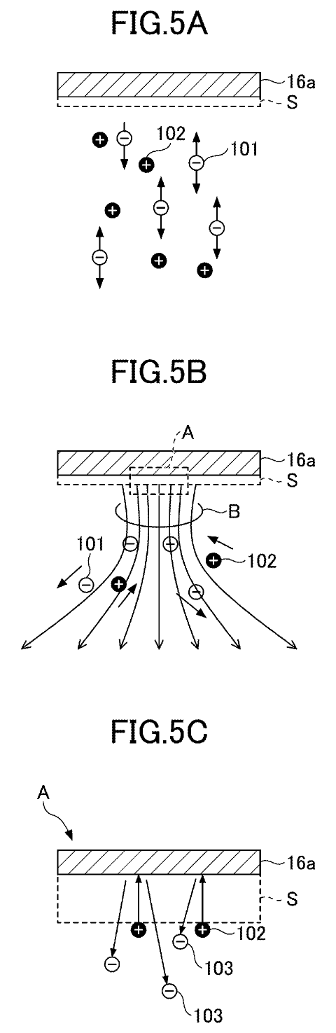

FIGS. 5A to 5C are diagrams illustrating cleaning of the upper electrode 16a as an example of parts inside a chamber according to one embodiment. FIG. 5A is a diagram illustrating the state of plasma when neither the electromagnet 30 nor the DC power supply 60 is used as a control knob for plasma control. FIG. 5B is a diagram illustrating the state of plasma when only the electromagnet 30 is used as a control knob. FIG. 5C is an enlarged view of a region near the central portion of the upper electrode 16a (see region A in FIG. 5B) and, unlike FIG. 5B, illustrates the state of plasma when both the electromagnet 30 and the DC power supply 60 are used as control knobs. In FIGS. 5A to 5C, S denotes a sheath.

In FIG. 5A, electrons 101 and ions 102 contained in plasma move between the upper electrode 16a and the lower electrode (base 14a). In FIG. 5B, electrons 101 in plasma are restricted by the magnetic field B generated in the plasma processing space by the electromagnet 30, and move while spreading in the horizontal direction toward the lower electrode (base 14a) side against the magnetic field B. Ions 102 (positive ions) can be collected inside the upper electrode 16a by repelling the movement of electrons.

In FIG. 5C, a DC voltage of negative polarity is applied to the upper electrode 16a while generating the magnetic field B of FIG. 5B. Thus, ions 102 collected inside the upper electrode 16a are drawn into the upper electrode 16a, accelerate toward the upper electrode 16a, and collide with the upper electrode 16a. By sputtering with the ions 102, secondary electrons 103 are emitted from the upper electrode 16a. The emitted secondary electrons 103 increase the plasma density below the central portion of the upper electrode 16a. This appears to indicate that the cleaning rate at the central portion of the upper electrode 16a can be locally increased.

The controller 2 may control the pressure inside the chamber 10 within a range of 1 mTorr to 100 mTorr (0.133 Pa to 13.3 Pa) based on the pressure inside the chamber detected by the pressure detector 70. By controlling the pressure inside the chamber 10 to be relatively low in this manner, ions can be easily collected at the central portion of the upper electrode 16a. As a result, the cleaning force at the central portion of the upper electrode 16a can be further increased.

### Experimental Example 2 of Cleaning Parts Inside Chamber

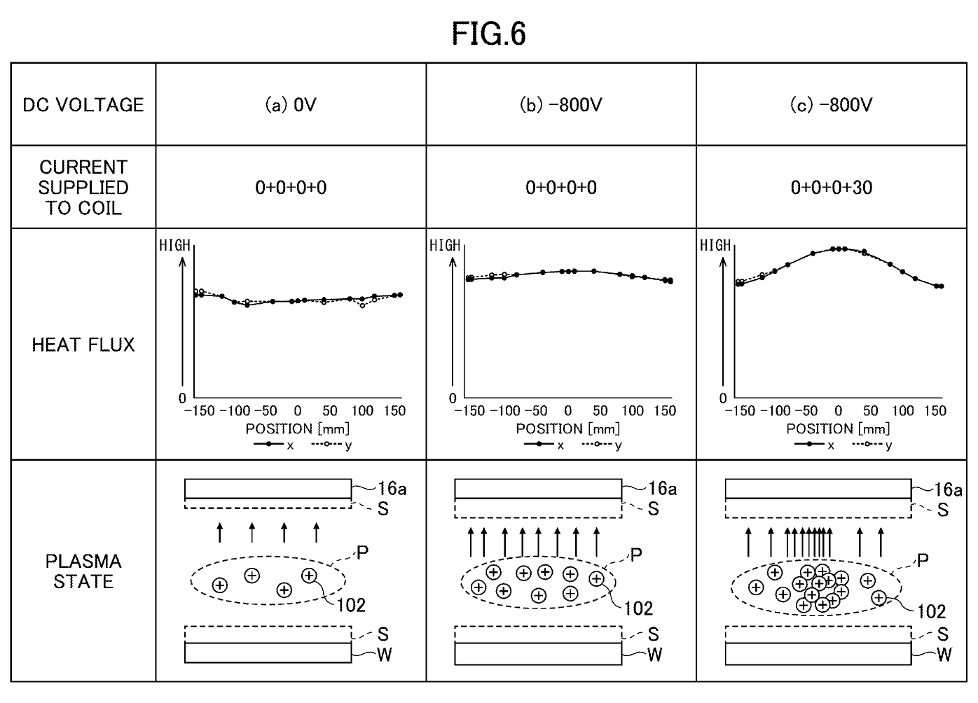

An experimental example (Experimental Example 2) of cleaning parts inside the chamber according to one embodiment will be described with reference to FIG. 6. FIG. 6 is a diagram illustrating Experimental Example 2 of cleaning parts inside the chamber according to the embodiment. The cleaning conditions in Experimental Example 2 are as follows. The plasma processing method performed under the cleaning conditions in Experimental Example 2 is an example of the plasma processing method according to one embodiment.

### Cleaning conditions in Experimental Example 2

Gas: CF₄, Ar, O₂

Source RF power: 600 W

Bias RF power: 550 W

DC voltage: Variable (0 V, −800 V)

Current supplied to coils 61–64: Variable

Without electromagnetic field: 0/0/0/0 dA (deciamperes)

With electromagnetic field: 0/0/0/30 dA (deciamperes)

Chamber pressure: 40 mTorr (5.33 Pa)

Under the cleaning conditions in Experiment Example 2, a processing gas (cleaning gas) consisting of CF₄ gas, Ar gas, and O₂ gas is supplied from the gas supply 11 and introduced into the plasma processing space 12s from the showerhead 16. Source RF power (HF power) of 600 W is supplied from the RF power supply 21 to the lower electrode (base 14a). Bias RF power (bias power) of 550 W is supplied from the RF power supply 23 to the lower electrode (base 14a). Thus, plasma is generated from the processing gas in the plasma processing space 12s. Further, experiments were conducted in a case where no DC voltage was applied from the DC power supply 60 to the upper electrode 16a ((a) in FIG. 6) and a case where a DC voltage of -800 V was applied ((b) and (c) in FIG. 6).

The graphs in FIG. 6 illustrate the results of Example 2, in which the heat flux at each position in the radial direction of the upper electrode 16a was measured. The heat flux in the radial direction of the upper electrode 16a is illustrated by solid lines with black circles for the X direction and by broken lines with white circles for the Y direction, which is perpendicular to the X direction. In the graphs of (a) to (c) of FIG. 6, there was no variation between the heat flux in the X direction and that in the Y direction, and both exhibited almost the same heat flux. Here, the term “heat flux” refers to a value obtained by multiplying the ion energy Ei (the energy of each ion) by the ion flux (the amount of ions). As the heat flux increases, the cleaning rate also increases.

The cleaning conditions in (a) of FIG. 6 are a case where the DC voltage to the upper electrode is 0 V, the current values supplied to the coils 61, 62, 63, and 64 are all 0, and no electromagnetic field is generated. Note that “0+0+0+0” in (a) of FIG. 6 indicates that the current values supplied to the coils 61, 62, 63, and 64 are all 0 dA (deciamperes).

The cleaning conditions illustrated in (b) of FIG. 6 are a case where the DC voltage to the upper electrode is -800 V, the current values supplied to the coils 61, 62, 63, and 64 are all 0 dA (deciamperes), and no electromagnetic field is generated.

The cleaning conditions illustrated in (c) of FIG. 6 are a case where the DC voltage to the upper electrode is -800 V, the current values supplied to the coils 61, 62, and 63 are 0, but the current value flowing through the coil 64 is 30 (dA), and an electromagnetic field is generated by the electromagnet 30. Note that “0+0+0+30” in (c) of FIG. 6 indicates that the current values supplied to the coils 61, 62, 63, and 64 are 0, 0, 0, and 30 dA (deciamperes).

In the graph illustrated in (a) of FIG. 6, the heat quantity at each position in the radial direction of the upper electrode 16a was generally constant, and the distribution of heat force was flat. In the graph illustrated in (b) of FIG. 6, when a DC voltage of -800 V was applied to the upper electrode 16a, the heat quantity increased over the entire radial direction of the upper electrode 16a as compared with the graph illustrated in (a) of FIG. 6. Because a DC voltage of -800 V was applied to the upper electrode 16a under the cleaning conditions illustrated in (b) of FIG. 6, as illustrated in “plasma state” in (a) and (b) of FIG. 6, the ion flux increased more than the plasma P illustrated in (a) of FIG. 6. This indicates that the heat quantity (Heat Flux) increased over the entire radial position of the upper electrode 16a. Therefore, by applying a DC voltage of -800 V to the upper electrode 16a, the overall cleaning rate could be increased.

In the cleaning condition in (b) of FIG. 6, an electromagnetic field was not generated by the electromagnet 30. On the other hand, in the cleaning condition of (c) of FIG. 6, an electromagnetic field was generated inside the chamber 10 by the electromagnet 30 while a DC voltage of -800 V was applied to the upper electrode 16a. Specifically, a current of 30 dA (deciamperes) was applied only to the coil 64.

As a result, as illustrated in the graph in (c) of FIG. 6, similarly to the graph in (b) of FIG. 6, a high heat quantity was maintained throughout the radial direction of the upper electrode 16a. In addition, compared with the graph in (b) of FIG. 6, the heat quantity at the central portion of the upper electrode 16a was further increased. This is because, as illustrated in the “plasma state” in (b) and (c) of FIG. 6, in the cleaning condition in (c) of FIG. 6, an electromagnetic field was generated inside the chamber 10 by the electromagnet 30 in addition to applying a DC voltage of −800 V to the upper electrode 16a. Accordingly, it is considered that the heat quantity increased throughout the radial direction of the upper electrode 16a due to the superimposed effect of the DC voltage and the electromagnetic field, and that ions were concentrated at the central portion of the upper electrode 16a, where a large number of secondary electrons were emitted, thereby further increasing the heat quantity at the central portion. Therefore, by applying a DC voltage of −800 V to the upper electrode 16a and generating an electromagnetic field inside the chamber 10 by the electromagnet 30, it is possible to increase the overall cleaning rate while further increasing the cleaning rate at the central portion of the upper electrode 16a.

### Plasma Processing Method

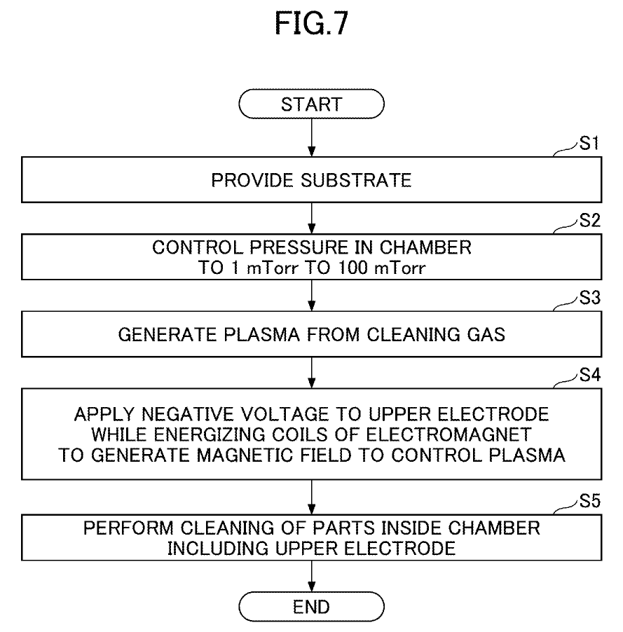

A plasma processing method according to an embodiment will be described with reference to FIG. 7. FIG. 7 is a flowchart illustrating an example of a plasma processing method according to the embodiment. The plasma processing method illustrated in FIG. 7 is controlled by the controller 2 and executed by the plasma processing apparatus 1.

When this processing is started, in step S1, the substrate W is carried into the chamber 10 and disposed on the substrate support surface of the substrate support 15. The substrate may be a product substrate or a dummy substrate. Note that the processing may proceed to step S2 without executing step S1. By executing step S1, the substrate can protect the substrate support surface from plasma during cleaning. By not executing step S1, the number of substrates used can be reduced.

Next, in step S2, the pressure inside the chamber 10 is controlled to 1 mTorr to 100 mTorr. Next, in step S3, cleaning gas is supplied into the chamber 10 from the gas supply 11, source RF power is applied to the lower electrode from the RF power supply 21, and plasma is generated from the cleaning gas. A bias RF power may be applied to the lower electrode from the RF power supply 23.

Next, in step S4, a negative DC voltage is applied to the upper electrode 16a while energizing the coils 61 to 64 of the electromagnet 30 to generate a magnetic field to control plasma. In step S5, the parts inside the chamber, including the upper electrode 16a, are cleaned. This increases the overall heat flux of the plasma, thereby increasing the overall cleaning rate of the parts inside the chamber, and also locally increasing the cleaning rate at the central portion of the upper electrode 16a. As a result, cleaning of the parts inside the chamber can be efficiently performed by both increasing the overall cleaning rate and further increasing the cleaning rate at the central portion of the upper electrode 16a, where the largest amount

of deposition occurs. Consequently, the cleaning time of the parts inside the chamber can be shortened, and throughput can be improved. In addition, unnecessary wear of uncontaminated parts inside the chamber can be suppressed.

### Cleaning Results

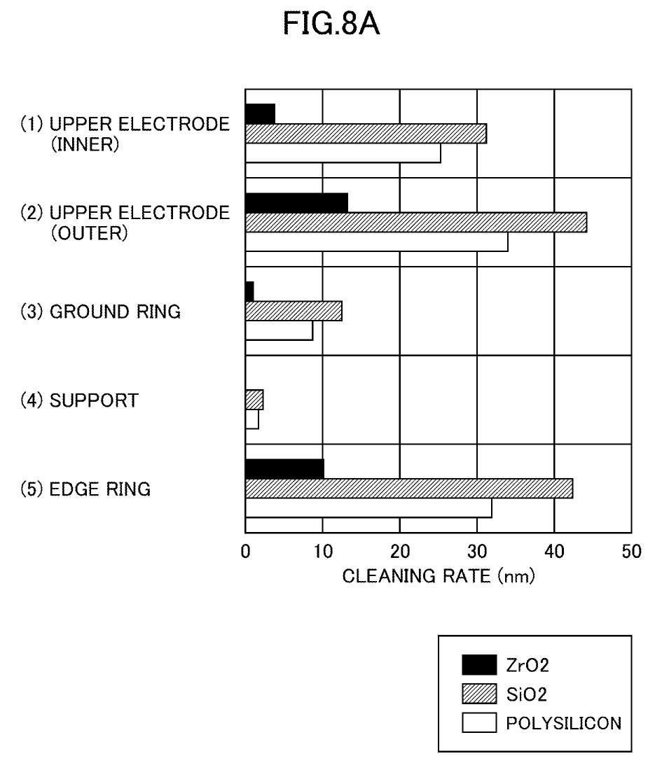

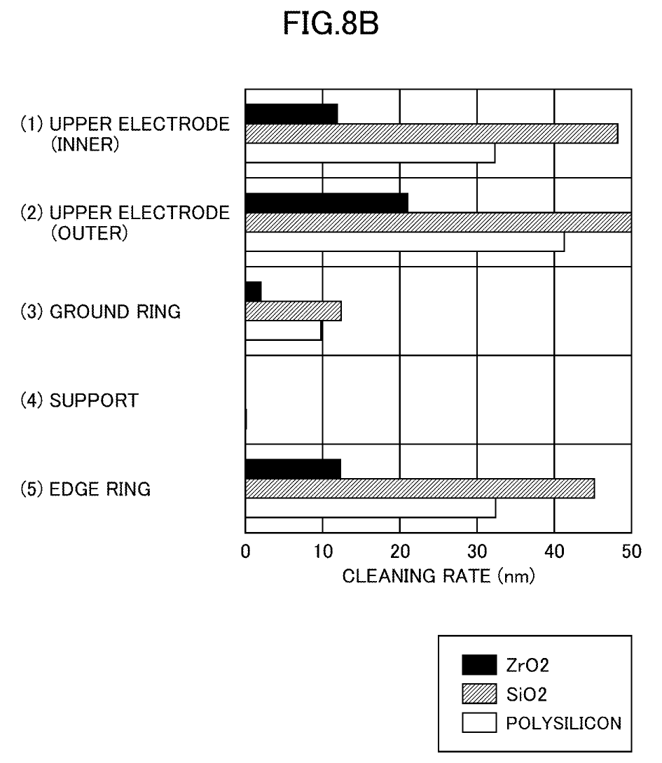

An example of the results of cleaning the parts inside the chamber by performing the plasma processing method according to the embodiment described above will be described with reference to FIGS. 8A and 8B. FIGS. 8A and 8B are diagrams illustrating an example of the cleaning results of parts inside the chamber.

FIGS. 8A and 8B illustrate the cleaning rates of five parts inside the chamber: (1) inner upper electrode 16a, (2) outer upper electrode 16b, (3) ground ring 41, (4) support 28, and (5) edge ring 26.

FIG. 8A illustrates the cleaning rates of respective parts inside the chamber when a magnetic field is not generated by the electromagnet 30 and a negative DC voltage is not applied to the upper electrode 16a. FIG. 8B illustrates the cleaning rates of respective parts inside the chamber when a magnetic field is not generated by the electromagnet 30 and a DC voltage of −500 V is applied to the upper electrode 16a. The cleaning conditions are as follows.

### Cleaning Conditions

Gas: CF₄, Ar, O₂

Source RF Power: 1000 W

Bias RF Power: 500 W

DC voltage: Variable (0 V, -500 V)

Chamber pressure: 20 mTorr (2.67 Pa)

Black bars in the graphs of FIGS. 8A and 8B are the results of measuring the cleaning rate of zirconium oxide (ZrO₂) specimens deposited on parts inside the chamber as deposits. Hatched bars in the graphs of FIGS. 8A and 8B are the results of measuring the cleaning rate of silicon oxide film (SiO₂) specimens deposited on the parts inside the chamber as deposits. White bars in the graphs of FIGS. 8A and 8B are the results of measuring the cleaning rate of polysilicon oxide film specimens deposited on the parts inside the chamber as deposits.

As compared with the results of FIG. 8A, when a negative DC voltage was applied to the upper electrode 16a without generating a magnetic field by the electromagnet 30, the cleaning rate of (1) the upper electrode 16a, (2) the upper electrode 16b, (3) the ground ring 41, and (5) the edge ring 26 illustrated in FIG. 8B increased. However, the in-plane uniformity of the cleaning rate of the upper electrodes could not be controlled without generating a magnetic field by the electromagnet 30.

From the above, the parts inside the chamber to be cleaned are preferably at least any one of the upper electrode 16a, the upper electrode 16b, the ground ring 41, and the edge ring 26. In particular, as illustrated in FIG. 8B, the cleaning rate of the upper electrode 16a and the upper electrode 16b increased compared to the results of FIG. 8A. Therefore, the upper electrode 16a and the upper electrode 16b are more preferable as the parts inside the chamber to be cleaned.

As described above, the central portion of the upper electrode 16a is closest to the substrate W, and about 50% of the deposit adheres to the central portion of the upper electrode 16a. Therefore, according to the plasma processing method according to the present embodiment, which utilizes a negative DC voltage and a magnetic field for plasma control, the central portion of the upper electrode 16a is cleaned locally, and the overall cleaning efficiency is also increased, thereby enabling uniform cleaning. In addition, unnecessary wear of the parts inside the chamber that are not contaminated can be suppressed.

### Others

The parts inside the chamber may include at least one selected from the group consisting of silicon, quartz, tungsten, molybdenum, ruthenium, and titanium. The parts inside the chamber may include at least any one of the upper electrode 16a, the upper electrode 16b, the ground ring 41, and the edge ring 26. Therefore, at least one of the upper electrode 16a, the upper electrode 16b, the ground ring 41, or the edge ring 26 may be formed from at least one selected from the group consisting of silicon, quartz, tungsten, molybdenum, ruthenium, and titanium.

In the step of cleaning the parts inside the chamber, the first period in which a magnetic field is generated in the chamber 10 by the electromagnet 30 and the second period in which a DC voltage is applied to the upper electrodes 16a and 16b by the DC power supply 60 may overlap or be slightly different from each other.

When cleaning the parts inside the chamber, the plasma density can be globally controlled in the first period, and the plasma density can be locally controlled in the second period.

As described above, according to the plasma processing method and the plasma processing apparatus according to the present embodiment, the parts inside the chamber can be efficiently cleaned.

The above-described embodiments include, for example, the following clauses.

### (Clause 1)

A plasma processing method executed by a plasma processing apparatus, the plasma processing apparatus including: a chamber; a substrate support disposed inside the chamber; an upper electrode facing a substrate support surface of the substrate support; an electromagnet disposed above the chamber; a plasma source configured to generate plasma inside the chamber; a DC power supply electrically coupled to the upper electrode; and one or more processors and one or more memories storing instructions that, when executed by the one or more processors, cause the plasma processing apparatus to perform the plasma processing method, the plasma processing method including:

generating plasma from a processing gas inside the chamber by the plasma source; and

controlling the plasma by applying a DC voltage to the upper electrode by the DC power supply while generating a magnetic field inside the chamber by the electromagnet, thereby cleaning parts inside the chamber.

### (Clause 2)

The plasma processing method according to Clause 1, wherein the parts inside the chamber include at least one selected from the group consisting of: the upper electrode; a ground ring disposed around the upper electrode and grounded; and an edge ring disposed around the substrate support.

(Clause 3)

The plasma processing method according to Clause 1 or 2, further including:

disposing a substrate or a dummy substrate on the substrate support surface.

### (Clause 4)

The plasma processing method according to any one of Clauses 1 to 3, further including:

disposing a substrate or a dummy substrate on the substrate support surface.

### (Clause 5)

The plasma processing method according to any one of Clauses 1 to 4, wherein the parts inside the chamber include at least one selected from the group consisting of silicon, quartz, tungsten, molybdenum, ruthenium, and titanium.

### (Clause 6)

The plasma processing method according to any one of Clauses 1 to 5, further including:

controlling a pressure inside the chamber in a range of 1 mTorr to 100 mTorr (0.133 Pa to 13.3 Pa).

### (Clause 7)

The plasma processing method according to any one of Clauses 1 to 6, wherein the cleaning of the parts is performed by applying a negative DC voltage

to the upper electrode by the DC power supply.

### (Clause 8)

A plasma processing apparatus including:

a chamber;

a substrate support disposed inside the chamber;

an upper electrode facing a substrate support surface of the substrate support;

an electromagnet disposed above the chamber;

a plasma source configured to generate plasma inside the chamber;

a DC power supply electrically coupled to the upper electrode; and

one or more processors and one or more memories storing instructions that, when executed by the one or more processors, cause the plasma processing apparatus to:

generate plasma from a processing gas inside the chamber by the plasma source; and

control the plasma by applying a DC voltage to the upper electrode by the DC power supply while generating a magnetic field inside the chamber by the electromagnet, thereby cleaning parts inside the chamber.

### (Clause 9)

The plasma processing apparatus according to Clause 8, wherein the electromagnet is annular and includes a plurality of coils arranged concentrically, and

the one or more processors cause the plasma processing apparatus to generate the magnetic field by energizing at least one of the plurality of coils.

### (Clause 10)

The plasma processing apparatus according to Clause 9, wherein the one or more processors cause the plasma processing apparatus to perform control in which energization amounts of the plurality of coils are adjusted on a coil-by-coil basis, and control in which a negative DC voltage is applied to the upper electrode, in a superimposed manner.

It should be noted that the invention is not limited to the configurations described in the above embodiments, and various combinations with other elements are also possible. These configurations can be modified as appropriate without departing from the scope of the invention, depending on the specific application. Furthermore, the features described in multiple embodiments may be applied in other configurations or combined with each other, as long as no contradictions arise.

According to one aspect of the present disclosure, parts inside the chamber can be efficiently cleaned.

What is claimed is:

1. A plasma processing method executed by a plasma processing apparatus, the plasma processing apparatus including: a chamber; a substrate support disposed inside the chamber; an upper electrode facing a substrate support surface of the substrate support; an electromagnet disposed above the chamber; a plasma source configured to generate plasma inside the chamber; a DC power supply electrically coupled to the upper electrode; and one or more processors and one or more memories storing instructions that, when executed by the one or more processors, cause the plasma processing apparatus to perform the plasma processing method, the plasma processing method comprising:
generating plasma from a processing gas inside the chamber by the plasma source; and
controlling the plasma by applying a DC voltage to the upper electrode by the DC power supply while generating a magnetic field inside the chamber by the electromagnet, thereby cleaning parts inside the chamber.

2. The plasma processing method according to claim 1, wherein the parts inside the chamber include at least one selected from the group consisting of: the upper electrode; a ground ring disposed around the upper electrode and grounded; and an edge ring disposed around the substrate support.

3. The plasma processing method according to claim 2, wherein the parts inside the chamber include the upper electrode.

4. The plasma processing method according to claim 1, further comprising:
disposing a substrate or a dummy substrate on the substrate support surface.

5. The plasma processing method according to claim 1, wherein the parts inside the chamber include at least one selected from the group consisting of silicon, quartz, tungsten, molybdenum, ruthenium, and titanium.

6. The plasma processing method according to claim 1, further comprising:
controlling a pressure inside the chamber in a range of 1 mTorr to 100 mTorr (0.133 Pa to 13.3 Pa).

7. The plasma processing method according to claim 1, wherein the cleaning of the parts is performed by applying a negative DC voltage to the upper electrode by the DC power supply.

8. A plasma processing apparatus comprising:
a chamber;
a substrate support disposed inside the chamber;
an upper electrode facing a substrate support surface of the substrate support;
an electromagnet disposed above the chamber;
a plasma source configured to generate plasma inside the chamber;
a DC power supply electrically coupled to the upper electrode; and
one or more processors and one or more memories storing instructions that, when executed by the one or more processors, cause the plasma processing apparatus to:
generate plasma from a processing gas inside the chamber by the plasma source; and
control the plasma by applying a DC voltage to the upper electrode by the DC power supply while generating a magnetic field inside the chamber by the electromagnet, thereby cleaning parts inside the chamber.

9. The plasma processing apparatus according to claim 8, wherein the electromagnet is annular and includes a plurality of coils arranged concentrically, and
the one or more processors cause the plasma processing apparatus to generate the magnetic field by energizing at least one of the plurality of coils.

10. The plasma processing apparatus according to claim 9, wherein the one or more processors cause the plasma processing apparatus to perform control in which energization amounts of the plurality of coils are adjusted on a coil-by-coil basis, and control in which a negative DC voltage is applied to the upper electrode, in a superimposed manner.
